(19) United States
(12) Patent Application Publication
(10) Pub. No.: US 2012/0100300 A1
(43) Pub. Date: Apr. 26, 2012

(54) PLASMA COATING SYSTEM AND METHOD FOR COATING OR TREATING THE SURFACE OF A SUBSTRATE

(76) Inventors: Malko Gindrat, Wohlen (CH); Philippe Guittienne, Belmont-sur-Lausanne (CH); Christoph Hollenstein, Lutry (CH)

(21) Appl. No.: 13/147,724

(22) PCT Filed: Jan. 15, 2010
(86) PCT No.: PCT/EP2010/050459

§ 371 Date: Nov. 23, 2011

(30) Foreign Application Priority Data
Feb. 5, 2009 (EP) 09152189.8

(51) Int. Cl. B05D 1/08; C23C 16/513

(52) U.S. Cl. 427/446; 118/723 E

(57) ABSTRACT

A plasma coating plant for coating or treating the surface of a substrate having a work chamber which can be evacuated and into which the substrate can be placed, and having a plasma torch for generating a plasma jet by heating a process gas, wherein the plasma torch has a nozzle through which the plasma jet can exit the plasma torch and can extend along a longitudinal axis (A) into the work chamber, wherein a mechanical limiting apparatus is provided downstream of the nozzle in the work chamber, which mechanical limiting apparatus extends along the longitudinal axis (A) and protects the plasma jet against an unwanted lateral intrusion of particles. A corresponding method is also disclosed.

The invention relates to a plasma coating plant and to a method for coating or treating a surface of a substrate in accordance with the preamble of the independent claim of the respective category.

From the numerous different processes of thermal spraying by means of plasma coating plants a few are carried out in the vacuum region, this means at a process pressure which is smaller than the air pressure of the environment. Such processes must naturally be carried out in evacuatable work chambers. In this respect pressures of only a few hundred millibar or even less are necessary in the work chamber depending on the process.

On plasma spraying it is common to generate a plasma jet by heating a process gas into which plasma jet the material required for the coating is typically introduced in powder form but also in fluid form, i.e. as gas or as liquid. In particular, on introduction of gas or of liquid it is also known to carry out the process of plasma spraying as a reactive process, i.e. to carry out the process in a comparable manner to a CVD process (chemical vapor deposition). In this respect the fluid introduced into the hot plasma jet is modified such that the desired substance for the coating only arises in the plasma jet, for example, through the breaking open of bonds or the dissection of molecules. The introduction of hexamethyldisiloxane (HMDSO) as a reactive substance to generate a silicon oxide layer on the substrate, e.g. a wafer is an example for this.

A known problem in these vacuum processes is that the plasma jet, which moves through the evacuated work chamber, leads to a suction effect in the region of the nozzle of the plasma jet. If a gas or a liquid is introduced into the plasma jet for a reactive process, powder particles or particles can arise through the modification. This can have the effect that particles—in particular at the boundary of the plasma jet—are deflected and move back in the direction of the nozzle and are then sucked back into the plasma jet through the sucking effect. Such “recycled” particles or powder particles which are not molten or sufficiently plastified generally lead to undesired faults in the coating generated on the substrate.

This problem also arises for processes in which a powder is introduced into the plasma jet. For example, non-molten or only partially molten and/or plastified powder particles are moved back in the direction of the nozzle in the same way as described above and are then sucked into the plasma jet. Also these powder particles or particles lead to undesired contaminations on the substrate.

This invention aims to remedy this problem. For this reason it is an object of the invention to propose a plasma coating plant and a method for coating or treating the surface of a substrate in which the undesired intrusion of particles into the plasma jet is at least significantly reduced.

The subject matter of the invention satisfying this object in view of the apparatus aspect and in view of the process engineering aspect are satisfied by the independent claims of the respective category.

Thus, in accordance with the invention a plasma coating plant for coating or treating the surface of a substrate is proposed, having a work chamber which can be evacuated and into which the substrate can be placed, and having a plasma torch for generating a plasma jet by heating a process gas, wherein the plasma torch has a nozzle through which the plasma jet can exit the plasma torch and can extend along a longitudinal axis into the work chamber, wherein a mechanical limiting apparatus is provided downstream of the nozzle in the work chamber, which mechanical limiting apparatus extends along the longitudinal axis and protects the plasma jet against an unwanted lateral intrusion of particles.

This limiting apparatus marks out the hot fast plasma jet with respect to the colder, calmer, i.e. essentially current-free vacuum and thereby prevents that particles are laterally sucked into the hot plasma jet in an undesired manner from the vacuum region. In this respect “lateral” and/or “from the side” means at an angle to or perpendicular to the longitudinal axis A.

The expansion of the plasma jet perpendicular to the longitudinal axis is limited by the limiting apparatus.

Thereby the plasma jet is surrounded and/or enclosed by the limiting apparatus so that no particles can arrive in the plasma jet from the side in an undesired manner.

The limiting apparatus is preferably arranged directly downstream of the nozzle of the plasma torch, as the suction effect is strongest here and thus the intrusion of particles is most probable here.

Advantageously, the limiting apparatus is configured as a tube, in particular as a metallic tube.

In accordance with a preferred embodiment, the limiting apparatus is configured as a cylindrical tube whose diameter is at most the ten-fold of the diameter of the nozzle at its outlet opening in particular is at most the five-fold of the diameter of the nozzle.

An injection apparatus is preferably further provided to inject a reactive fluid into the plasma jet for carrying out reactive processes.

A possible design is present when the injection apparatus includes a ring-shaped injection nozzle which is arranged in the limiting apparatus.

In accordance with a preferred embodiment a substrate holder for holding a substrate is provided, wherein the limiting apparatus extends over at least 80% of the distance between the nozzle and the substrate holder, preferably over at least 90% of the distance. The plasma jet is essentially protected against contamination over its overall length from the nozzle of the plasma torch up to a substrate through this measure.

Furthermore, a method for coating or treating the surface of a substrate by means of a plasma coating plant is proposed by the invention in which the substrate is placed into a work chamber, the work chamber is evacuated to a pressure of less than one bar, a plasma jet is generated by means of a plasma torch by heating a process gas, which plasma jet exits the plasma torch through a nozzle and can extend along a longitudinal axis in the work chamber, wherein the plasma jet is protected against an unwanted lateral intrusion of particles by a mechanical limiting apparatus which extends along the longitudinal axis.

The widening of the plasma jet perpendicular to the longitudinal axis down-stream of the nozzle is limited in the work chamber through the mechanical limiting apparatus.

Preferably a reactive fluid is injected into the plasma jet by means of an injection apparatus for carrying out reactive processes.

It is a preferred measure, also from a process engineering point of view, when the plasma jet is protected by the limiting apparatus over at least 80% of its length between the nozzle and the substrate, preferably over at least 90% of its length.

The method in accordance with the invention is suitable, in particular for such processes in which the process pressure in the work chamber is at most 100 mbar on coating, preferably at most 50 mbar and especially at most 30 mbar. The danger of the unwanted recirculation and/or the unwanted suction of particles from the vacuum region into the plasma jet is namely especially pronounced, in particular for low process pressures. Such particles, which can be present, e.g. as molecules, free radicals or as other very small particles—also in the nanometer region—have an increased free path length in vacuum at low process pressures so that the probability increases that such particles intrude the plasma jet and/or are sucked into this. At atmospheric pressure or even higher process pressures such particles would be directly decelerated as a rule as soon as they laterally leave the plasma jet.

Further advantageous measures and embodiments result from the dependent claims.

In the following the invention will be explained in detail both in view of the apparatus aspect and also in view of the process engineering aspect with reference to embodiments and with reference to the drawing. In the schematic drawing, not drawn to scale, there is shown:

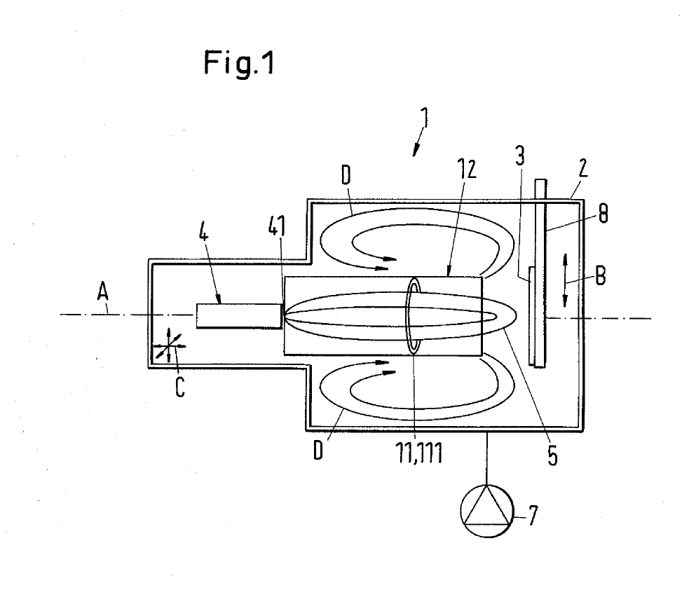

FIG. 1 an embodiment of a plasma coating plant in accordance with the invention,

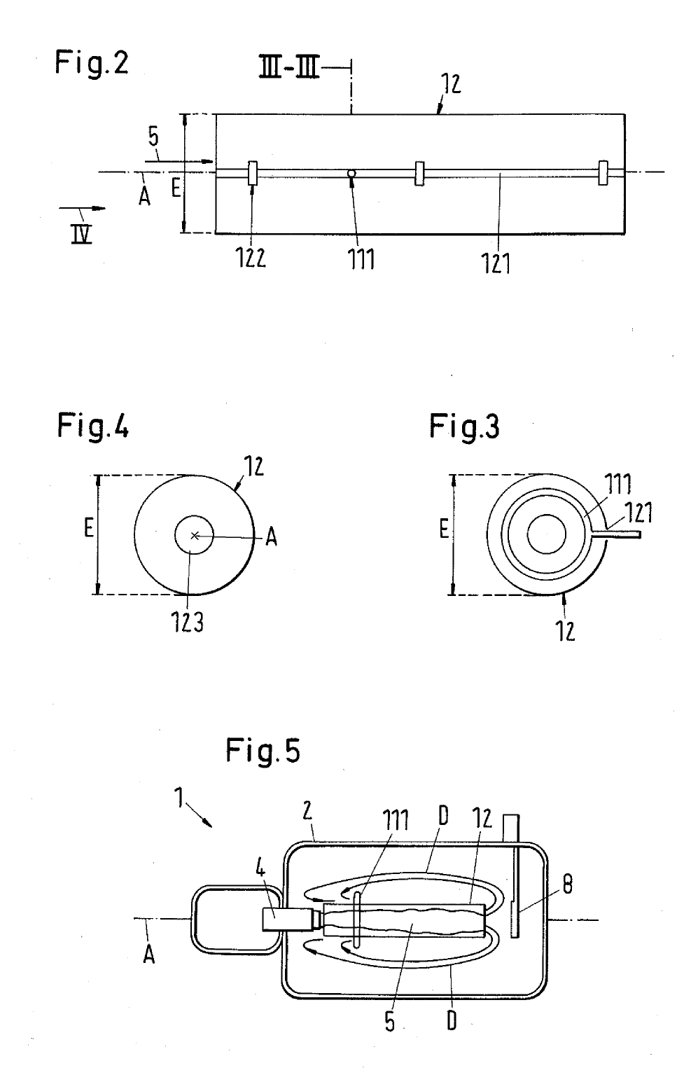

FIG. 2 a view of the coating plant of FIG. 1,

FIG. 3 a section through the coating apparatus along the sectional line III-III of FIG. 2,

FIG. 4 a top view onto the limiting apparatus from the viewing direction IV of FIG. 2, and

FIG. 5 a variant for the embodiment from FIG. 1.

In the following the invention will be explained with reference to an example particularly relevant for practice, namely with reference to a reactive plasma spray process. In this respect a liquid or a gas-like starting material is introduced into the plasma jet. The molecules or components of the fluid starting material are modified by the high energies of the plasma jet, for example, by the splitting of bonds, the splitting of components etc., whereby the desired components for the coating arise. Such processes are also comparable to CVD processes in principle, for which reason they are sometimes referred to as reactive thermal CVD process. The so-called low pressure plasma spraying (LPPS) and the low pressure plasma spraying—thin film-method (LPPS-TF) are especially suitable for this kind of a method.

It is naturally understood, however, that the invention is by no means restricted to the this reactive plasma spray processes. It is suitable in an analogous equal manner for all plasma spray processes which are carried out in vacuum, i.e. at a process pressure which is smaller than the surrounding air pressure. As the initially mentioned problem of recirculation of powder particles and particles arises in these vacuum plasma spray processes, which should be satisfied by the invention or at least be reduced by the invention. In particular the invention is also suitable for such vacuum plasma spray processes in which a powder-shaped starting material is introduced into the plasma jet.

A schematic illustration of an embodiment of a plasma coating plant in accordance with the invention, which is referred to totally with the reference numeral 1, is shown in FIG. 1. The plasma coating plant 1 includes a work chamber 2 having a plasma torch 4 for generating a plasma jet 5 by heating a process gas. The plasma jet 5 exits through a nozzle 41 of the plasma torch 4 and, in the operating state, widens along the longitudinal axis A. A controlled pump apparatus 7 is further provided which is connected to the work chamber 2 to set the process pressure in the work chamber 2. A substrate holder 8 for holding a substrate 3 is provided in the work chamber 2 which can be movably designed at least in one direction perpendicular to the longitudinal axis A, as is indicated by the double arrow B in FIG. 1. Through this the substrate 3 can be moved perpendicular to the longitudinal axis A so that different regions of the substrate 3 can be gradually subjected to the plasma jet 5. Additionally or alternatively hereto the substrate holder 8 can be configured such that the substrate can be rotated during the treatment or coating if required.

The plasma torch 4 is also preferably arranged on a two-axis or a three-axis displacement holder as is indicated by the arrows C in FIG. 1, so that the relative position of the plasma torch 4 and thereby the relative position of the nozzle 41 to the substrate 3 can be changed in two or three dimensions. In particular the distance from the nozzle 41 to the substrate 3 can be changed.

With regard to further details of the design of the plasma spray plant 1 and in particular with regard to the process parameter regions and the injection into the plasma jet 5 one is referred to the European patent application no. 08154091.6 of the same applicant at this point in time.

The liquid and/or gas-shaped starting material which is injected into the plasma jet 5 on reactive plasma spraying can be introduced into the plasma jet 5 at different positions, for example in the nozzle 41 or upstream directly in front of the nozzle 41 or together with the process gas in the axial direction, i.e. in the direction of the longitudinal axis A or also through an injection apparatus 11 which is arranged further away downstream of the nozzle. Naturally, also a combination of these variants is possible. In particular with regard to the introduction of fluid media into the plasma jet 5 reference is made to EP-A-1 895 818 of the same applicant as well as to the previously cited European patent application no. 08154091.6 of the same applicant.

In accordance with the invention a mechanical limiting apparatus 12 is provided in the work chamber 2 which extends along the longitudinal axis A and protects the plasma jet 5 against an unwanted lateral intrusion of particles. Furthermore, the widening of the plasma jet perpendicular to the longitudinal axis A is limited hereby, the hot plasma jet is marked out with respect to the colder vacuum region. In the present embodiment, the limiting apparatus is configured as a cylindrical tube which extends in the direction of the longitudinal axis A and runs coaxially to the longitudinal axis A. The limiting apparatus 12 is preferably manufactured from a metallic material, in particular a metal or an alloy.

The recirculation of particles or of powder particles is efficiently prevented through the limiting apparatus as is indicated by the arrows D in FIG. 1. It is thereby prevented that the particles moving backwards laterally—i.e. at an angle to or perpendicular to the longitudinal axis A—can intrude the plasma jet in the direction of the nozzle 41 through the sucking effect of the plasma jet 5. The quality of the coating manufactured on the substrate can be significantly improved through this measure.

The limiting apparatus 12 preferably starts directly downstream of the nozzle 41. In dependence on the construction type it can also bound at the nozzle 41. It is further preferred when the limiting apparatus 12 extends over at least 80%, preferably over at least 90% of the distance between the nozzle 41 and the substrate 3 as the plasma jet is essentially protected over its overall length between the nozzle 41 and the substrate 3 in this way. Particles can no longer intrude in an undesired manner from the side, i.e. at an angle to or perpendicular to the longitudinal axis from the vacuum region into the plasma jet 5.

This protection of the plasma jet 5 is also particularly important when—as is the case for the embodiment described here—the injection apparatus 11 is provided further downstream of the nozzle 41.

The respective dimensions of the limiting apparatus 12 depend on the specific case of application and can be optimized for this. The limiting apparatus 12 should preferably be dimensioned such that it completely surrounds the plasma jet with regard to the lateral direction—i.e. perpendicular to the longitudinal axis A—this means in the region of the limiting apparatus 12 the plasma jet should run essentially completely within the limiting apparatus 12. On the one hand, the diameter of the limiting apparatus 12 is not allowed to be too small and/or its clear width perpendicular to the longitudinal axis A should not be too small, as then the thermal energy transfer from the plasma jet 5 onto the limiting apparatus 12 is too strong and can damage the latter. On the other hand, the diameter of the limiting apparatus 12 and/or its clear width perpendicular to the longitudinal axis A cannot be so large that the limiting apparatus 12 no longer represents an actual limitation for the lateral widening (perpendicular to the longitudinal axis A) of the plasma jet, for example, the danger would then arise that an undesired recirculation of particles arises within the limiting apparatus.

The limiting apparatus is not essential for the shaping of the plasma jet or for the guiding of the plasma jet as the shape or form of the plasma jet is substantially determined by the pressure conditions and energy conditions as well as the gas flows. The limiting apparatus bounds the hot plasma jet against the cool vacuum.

The suitable diameter and/or the clear width of the limiting apparatus thereby depend on the plasma jet and in particular on its lateral widening which it would have without the limiting apparatus. Thus, for example, the lateral widening of the plasma jet is larger the lower the process pressure is in the work chamber and the larger the plasma power is. It is possible for the person of ordinary skill in the art to adapt the dimensions of the limiting apparatus for each case of application.

In practice diameters of at least 5 to 10 cm and up to 50 cm are especially suitable for cylindrical tube-like limiting apparatuses 12.

Naturally it is not necessary that the limiting apparatus 12 is configured as a cylindrical tube, but also other shapes of cross-sections such as rectangular, multi-angular or oval or other curvatures are possible. It can also be advantageous when the limiting apparatus 12 changes its cross-sectional area in the direction of the longitudinal axis A.

The FIGS. 2 to 4 show the limiting apparatus 12 in more detail. FIG. 2 shows a side view of the limiting apparatus 12 of FIG. 1. The limiting apparatus 12 is configured as a metallic cylindrical tube 12 which extends in the direction of the longitudinal axis A and has a diameter E. The tube is laterally provided with a slot 121 which allows a monitoring of the plasma jet during operation and, for example, can also serve for the reception of sensors. Holding elements 122 are provided for stabilization.

The slot 121 further serves for the reception of a ring-shaped injection nozzle 111 which is part of the injection apparatus 11 by means of which the reactive fluid is introducible into the plasma jet. With regard to this ring nozzle 111 one is in turn again referred to the already cited European patent application no. 08154091.6 of the same applicant.

FIG. 3 shows a section through the limiting apparatus along the sectional line III-III in FIG. 2. In particular also the ring-shaped injection nozzle 111 can be recognized here.

FIG. 4 shows a top view onto the limiting apparatus 12 from the viewing direction IV in FIG. 2 and shows an inlet opening 123 of the limiting apparatus 12.

It is understood that for such vacuum processes in which no fluid is introduced into the plasma jet 5, but, for example, a powder one can do without the injection apparatus 11 and/or the ring-shaped injection nozzle 111.

Finally, FIG. 5 also shows, in an analogous illustration to FIG. 1, a variant for the embodiment of the plasma coating plant 1. In contrast to FIG. 1, the ring-shaped injection nozzle is provided outside of the limiting apparatus 12 in this variant so that it surrounds the limiting apparatus 12. It is understood that at least a gap or a nozzle-shaped connection opening must be provided through which the fluid is introducible into the plasma jet.

In an embodiment of the method in accordance with the invention, the manufacture and application of a thin SiOₓ layer by means of a reactive thermal low pressure plasma is explained in detail. A commercially available plasma torch having a power for thermal plasma spraying can be used for the manufacture, for example a plasma torch having three cathodes and a cascaded anode equipped with water cooling. A plasma torch especially suitable for this, is distributed by the applicant under the name TriplexPro. Argon, a mixture of argon and hydrogen or argon and helium can be used as a plasma gas and the reactive components which are injected into the plasma jet can, for example, be composed of a mixture of gas-shaped hexamethyldisiloxane (HMDSO) with oxygen. The oxygen proportion in the HMDSO/O₂ mixture is typically about 2% to 3% with regard to the gas flow. To achieve a higher gas exploitation the reactive component is injected into the plasma jet 5 by means of the ring-shaped injection nozzle 111. The distance between the substrate 3 and the injection nozzle 111 amounts to approximately 77 cm. The distance of the nozzle 41 of the plasma torch 4 from the substrate amounts to approximately 1 m, the process pressure in the work chamber is 0.2 mbar up to 1 mbar, in particular approximately 0.5 mbar and the power supplied to the plasma torch is 8 kW up to 16 kW. The oxygen flow amounts to approximately 3.4 liters per minute.

In this manner high quality SiOₓ layers, for example, of 2 μm thickness, but also having a thickness smaller than or equal to 10 to 20 μm can be applied. The deposition rate on a 30 cm×30 cm large substrate lies at typically 10 nm/s or higher, wherein an increased gas exploitation can be achieved with regard to the supplied HMDSO gas. The SiOₓ layers are characterized by a high purity. In particular the milky look of the coating on the substrate 3 which is frequently recognizable without the limiting apparatus 11 can no longer be seen and/or is significantly reduced.

1. A plasma coating plant for coating or treating the surface of a substrate, having a work chamber which can be evacuated and into which the substrate can be placed, and having a plasma torch for generating a plasma jet by heating a process gas, wherein the plasma torch has a nozzle through which the plasma jet can exit the plasma torch and can extend along a longitudinal axis (A) into the work chamber wherein a mechanical limiting apparatus is provided downstream of the nozzle in the work chamber, which mechanical limiting apparatus extends along the longitudinal axis (A) and protects the plasma jet against an unwanted lateral intrusion of particles.

2. The plasma coating plant in accordance with claim 1, wherein the limiting apparatus is arranged directly downstream of the nozzle of the plasma torch.

3. The plasma coating plant in accordance with claim 1, wherein the limiting apparatus is at least one of a tube and a metallic tube.

4. The plasma coating plant according to claim 1, wherein the limiting apparatus is configured as a cylindrical tube whose diameter (E) is at most the ten-fold of the diameter of the nozzle at its outlet opening.

5. The plasma coating plant according to claim, wherein an injection apparatus is further provided to inject a reactive fluid into the plasma jet.

6. The plasma coating plant in accordance with claim 5, wherein the injection apparatus includes a ring-shaped injection nozzle which is arranged in the limiting apparatus.

7. The plasma coating plant according to claim 1, further comprising a substrate holder for holding a substrate, wherein the limiting apparatus extends over at least 80% of the distance between the nozzle and the substrate holder.

8. A method of coating or treating the surface of a substrate by means of a plasma coating plant in which the substrate is placed into a work chamber, the work chamber is evacuated to a pressure of less than 1 bar, a plasma jet is generated by means of a plasma torch by heating a process gas, which plasma jet exits the plasma torch through a nozzle and can extend along a longitudinal axis (A) in the work chamber wherein the plasma jet is protected against an unwanted lateral intrusion of particles by a mechanical limiting apparatus which extends along the longitudinal axis (A).

9. The method in accordance with claim 8, wherein a reactive fluid is injected into the plasma jet by means of an injection apparatus.

10. The method in accordance with claim 8, wherein the plasma jet is protected by the limiting apparatus over at least 80% of its length between the nozzle and the substrate (3).

11. The method in accordance with claim 8, in which a process pressure in the work chamber is at most 100 mbar on coating.

12. The plasma coating plant according to claim 1, wherein the limiting apparatus is configured as a cylindrical tube whose diameter (E) is at most the five-fold of the diameter of the nozzle at its outlet opening.

13. The plasma coating plant according to claim 1, further comprising a substrate holder for holding a substrate, wherein the limiting apparatus extends over at least 90% of the distance between the nozzle and the substrate holder.

14. The method in accordance with claim 8, wherein the plasma jet is protected by the limiting apparatus over at least 90% of its length between the nozzle and the substrate (3).

15. The method in accordance with claim 8, in which a process pressure in the work chamber is at most 50 mbar on coating.

16. The method in accordance with claim 8, in which a process pressure in the work chamber is at most 30 mbar on coating.
